(19) United States
(12) Patent Application Publication
(10) Pub. No.: US 2008/0157665 A1
(43) Pub. Date: Jul. 3, 2008

(54) Optical Thin Films with Nano-Corrugated Surface Topologies by a Simple Coating Method

(75) Inventors: Xiaodong Wu, Lancaster, PA (US); Arthur Jin-Ming Yang, Bethesda, MD (US); Ruiyun Zhang, York, PA (US)

Correspondence Address: JONES DAY, 222 EAST 41ST ST, NEW YORK, NY, 10017, US

(73) Assignee: Optimax Technology Corporation, Ping Chen (TW)

(21) Appl. No.: 11/884,834

(22) PCT Filed: Feb. 23, 2006
(86) PCT No.: PCT/US06/06240

§ 371 Date: Aug. 22, 2007

Related U.S. Application Data
(60) Provisional application No. 60/656,097, filed on Feb. 25, 2005.

(51) Int. Cl. H01J 1/62; B05D 5/12

(52) U.S. Cl. 313/506; 427/66

(57) ABSTRACT

Embodiments of the invention relate to functionalized nanoparticle coating compositions. These coating can improve the light extraction efficiency of light emitting devices, including LEDs and OLEDs. In some embodiments, the coating can improve other properties such as anti-staining, abrasion and/or scratch resistance.

### CROSS-REFERENCE TO RELATED APPLICATION

This application claims benefit of U.S. Provisional Application No. 60/656,097 filed Feb. 25, 2005. This application, in its entirety, is incorporated herein by reference.

### BACKGROUND OF THE INVENTION

An embodiment of this invention relates to inorganic-organic self assembled functional coatings that can easily achieve a well controlled surface topography at the visible light wavelength scale. Embodiments of the invention may be used to improve light extraction efficiency in light emitting devices (LED) and organic light emitting devices (OLED).

At present, LEDs are the most efficient sources of colored light in almost the entire visible spectral range. Solid-state lighting may use visible and/or ultraviolet LEDs that are expected to reach lifetimes exceeding 100,000 hours. Using organic materials for light emitting devices (LED) has also gained tremendous interest due to their versatility in processing and the relative ease of composition control as well as their ability to be fine tune their properties by chemical means. Nowadays, high efficiency light emitting devices, such as LEDs and OLEDs, are desired for many applications such as displays, cellular phones, digital cameras and camcorders, gaming devices, PDAs and optical communication systems. The increasing capabilities of small displays require energy efficient LEDs with enhanced brightness and luminance. Future large-scale use of LED as general lighting devices would benefit substantially from enhanced efficiencies.

The light output efficiency of current OLEDs could be enhanced by new designs. The decay of excitons within the emissive organic layer may take many forms other than the desired light output, including power losses to wave-guided modes, surface plasmon-polariton (SPP) modes, or dissipation by absorption in the electrodes and organic layers. Because of efficiency requirements of portable devices and detrimental effects of excessive heat, light outcoupling has become one of the central issues in improving light emitting devices. The large difference in the refractive index among the different layers within a device could trap a significant amount of light simply by total internal reflection. In addition, SPP modes are non-radiating electromagnetic surface modes at the interface between a metal and a dielectric layer or two dielectric layers. It has been shown by modeling that the power loss could account for up to 80% of the power that would otherwise have been radiated. The trapped amount of power is eventually converted to heat, which leads to overheating of the device and is detrimental to the lifetime and usage of the device.

Several methods to improve light emitting device efficiencies by fabricating wavelength scale periodicity on device surface have been reported in the prior art which include lithographic, hot embossing, moulding, and gratings. However, all these methods require not only sophisticated equipment, but also multiple steps in processing and excessive energy input to generate the desired periodic photonic type structures.

Representative examples of recent U.S. patent art relating to light emitting devices or light emitting diodes, including both inorganic and organic based materials, and methods for improving the light emitting efficiencies thereof, include: Krares, et al, U.S. Pat. No. 5,779,924; Duggal et al, U.S. Pat. No. 6,538,375; Kawase, U.S. Pat. No. 6,661,034; Arnold et al, U.S. Pat. No. 6,670,772; Cok et al, U.S. Pat. No. 6,787,990; Nitta et al, U.S. Pat. No. 6,803,603; Kawase, U.S. Pat. No. 6,815,886; Erchak, U.S. Pat. No. 6,831,302; Okazaki et al, U.S. Pat. No. 6,924,163; Suchiro et al, U.S. Pat. No. 6,946,788; Tyan et al, U.S. Pat. No. 6,965,197; Samuel et al, U.S. Pat. No. 6,967,437. The disclosures of each of these references are incorporated herein, in their entirety, by reference thereto, especially with regard to the descriptions of the light emitting devices or light emitting diodes and the various modes of operation thereof and materials thereof, as generally all well known in the art.

### BRIEF DESCRIPTION OF THE DRAWINGS

FIG. 1 is a schematic drawing of a cross-section illustrating one potential application of an optical coating on a generic emitting substrate of OLEDs.

FIGS. 2(a), 2(b) and 2(c), are the surface topographical studies by AFM imaging, AFM 3D height imaging and Fourier Transform of the AFM height image, respectively, of a functional coating layer, specifically, Sample A, according to an embodiment of the invention.

FIGS. 3(a), 3(b), and 3(c), are the surface topographical studies by AFM imaging, AFM 3D height imaging and Fourier Transform of the AFM height image, respectively, of a functional coating layer, specifically, Sample D, according to another embodiment of the invention.

FIG. 4 is a graphic representation illustrating the correlation between the length scale of the functional coating surface microstructure and the silica nanoparticles according to an embodiment of the invention.

FIG. 5 is a graphic representation of a luminance enhancement study of the coated area versus uncoated area of an OLED between 3V and 7V applied voltage, for Example A (▪) and Example D (♦).

### SUMMARY OF THE INVENTION

The present invention, in various embodiments thereof, provides an inexpensive method to produce an inorganic-organic thin film having a well-controlled surface morphology and a refractive index matching to that of the encapsulated material, which may be, for example, either plastic or glass. The coating can be applied by dip or spin coating or other wet coating methods on the surface of a substrate prior or after manufacturing the light emitting device.

An inorganic-organic self assembled functional coating, which offers an easy and effective way to fabricate visible light wavelength scale microstructures on both glass as well as plastic substrates is described below.

In addition, because the creation of the surface morphology is accomplished by using nanoparticles in an ordinary coating process, it can be easily integrated with other functional coatings, such as quantum dots, fluorescent core-shell nanoparticles, and metal nanomaterials, to further enhance the light extraction efficiency of the solid state lighting devices. For example, as demonstrated by examples of embodiments of this invention, as presented hereinafter, the functional coating can be used as the effective binding matrix for highly efficient phosphor materials, such as quantum dots or fluorescent core-shell nanoparticles, to make high bright white light emitting devices. In addition, the surface corrugation can be easily created with a functional coating of good mechanical properties to provide protection against abrasions and scratches. Either a sol-based binder or a polymer-based binder may be used to enhance the adhesion between silica particles as well as to match the refractive index of the nanoparticles. As an example, inorganic-organic hybrid coating compositions based on a UV-curable or heat-curable binder and inorganic particles with special surface modification have been developed according to embodiments of this invention.

For instance, as demonstrated by examples of this invention as presented hereinafter, the length scale of surface corrugation which enhances LED and OLED performance is close to the wavelength of visible light. Consequently, a layer of thin coating (i.e. thickness is much less than the wavelength of visible light) can be applied on top of the corrugated surface to provide an anti-staining function. Anti-staining is another important benefit obtainable from optical coatings for OLED devices and applications according to various embodiments of this invention. The outmost layer may be treated with a very thin hydrophobic layer to improve the anti-staining properties. A light outcoupling enhancement coating for solid state lighting devices with improved resistance to staining, abrasion, scratch, weathering, and chemicals, can be accomplished by a composite coating layer as disclosed herein.

According to an embodiment of the present invention there is provided a coating composition, which contains fluorocarbon surface modified silica (F-silica) particles with very low surface tension. The functional coating containing F-silica particles and inorganic-organic hybrid matrix can promote a self-assembly process during the coating formation and the dispersed fluorinated silica particles, because of their low-energy surface, migrate to the top surface of the coating layer and form a visible light wavelength scale microstructure, thus offering optimized recovery of SPP modes.

Further, according to embodiments of the invention the length scale of the coating surface topography may be precisely controlled by the adjustments of the size of the synthesized particles and the corresponding processing conditions of such a coating.

Accordingly, in an embodiment of the invention, there is provided a method for controlling surface corrugation of an emitting surface of an organic light-emitting device (OLED) which includes applying to the surface a functional coating containing nanoparticles having fluorinated organic functional groups bonded thereto.

In one aspect of this embodiment of the invention, the nanoparticles may be substantially spherical silica nanoparticles with fluorine functional groups and/or crosslinkable organic functional groups, and wherein the particle size may range from about 20 nm to about 600 nm.

In another aspect of this embodiment, the functional coating may include a silica sol with organic functional groups bonded thereto.

In another aspect of this embodiment, the functional coating may include a photoinitiator.

In another aspect of this embodiment, the functional coating may include a mixture of fluorinated silica particles, silica sol and photoinitiator.

In another aspect of this embodiment, the functional coating may include polymerizable monomers and/or oligomers with di- or multi-functional groups, which may be included in admixture with fluorinated silica particles and/or photoinitiator.

In another aspect of this embodiment, the functional coating may be applied to a suitable substrate, such as plastic or inorganic glass by dip coating or spin coating.

In an embodiment of the preceding aspect, the functional coating may be formed by dip or spin coating the emitting surface with a precursor solution to form a mixture of silica nanoparticles and polymeric binder. The coated functional coating may be post-treated, such as by heat treating at a temperature of from about 40° C. to about 100° C., for a period of time which may range, for example, from about 1 minute to about 300 minutes.

In another aspect of the invention, the coated functional coating may be further treated by exposure to UV radiation.

In a related aspect of the foregoing embodiments of the invention, the coated functional coating may be used as a binding matrix for particles, including metal nanoparticles, metal-silica core-shell nanoparticles or high efficiency phosphor materials, such as, for example, quantum dots or fluorescent core-shell nanoparticles.

In another embodiment of the invention there is provided a method for enhancing light extracting efficiency of a light emitting device, which includes applying to the emitting surface of an LED or an OLED device a coating which includes a precisely controlled corrugated surface, the coating including a functional coating containing sol-gel nanoparticles having fluorinated organic functional groups bonded thereto.

In another embodiment of the invention there is provided a method for enhancing light extraction efficiency of a light emitting device, including applying inside the multilayer microcavity structure of an OLED device, which may, for example, be a bottom-emitting OLED or a top-emitting OLED, or a dual-emitting OLED, (depending on the choice of the light output (transparent) layer) a coating including a precisely controlled corrugated surface, wherein the coating includes a functional coating containing sol-gel nanoparticles having fluorinated organic functional groups bonded thereto and a conformal metal layer of thickness range of about 10 to about 70 nm.

In another embodiment of the invention there is provided a method for achieving a lotus-leaf effect on a substrate, including applying to the substrate a precisely controlled functional coating containing nanoparticles having fluorinated organic functional groups bonded thereto.

According to another embodiment of the invention there is provided a light-emitting element which includes a light-emitting layer; and at least one light-extracting portion; wherein a part of the at least one-light extracting portion includes surface corrugation with controlled length scale, correlating with the desired light enhancement wavelength, wherein the surface corrugation includes a self-assembled layer of nanoparticles with controlled size and having fluorinated organic functional groups bonded thereto to facilitate assembling at the surface layer.

In still another embodiment of the invention there is provided a method for improving the light-emitting efficiency of a light-emitting device which includes (a) a substrate, (b) a first electrode disposed over the substrate, (c) an organic EL (electroluminescent) element disposed over the transparent first electrode providing a light-emissive function for producing light, (d) a second electrode layer disposed over the EL layer, wherein at least one of the first and second electrodes may be transparent, such that the light-emitting device may be top-emitting, bottom emitting or dual emitting; the method includes the steps of applying to at least one of the layers (a)-(d), a surface corrugated layer with a controlled length scale optimized for light extraction and comprising a self-assembled layer of nanoparticles having fluorinated organic functional groups bonded thereto, thereby facilitating formation of the desired surface corrugation at the optimized length scale.

In one aspect of the preceding embodiment, the light-emitting device may be a bottom-emitting device wherein the surface corrugated layer may be applied to the surface of the substrate which is opposed to the surface on which the first electrode is disposed and the first electrode is transparent and the second electrode is made from a reflecting material or includes a layer of reflecting material applied thereto.

In another aspect of the above embodiment the light-emitting device may be a top-emitting device and the surface corrugated layer may be interposed between the second electrode and the EL element and the first electrode, may be made from a reflecting layer or may include a reflecting layer on either side thereof. For a dual emitting device both upper and lower surface layers may be made transparent.

In still another embodiment of the invention there is provided an enhanced light-emitting device which includes (a) a transparent substrate; (b) a first electrode layer disposed over a first surface of the transparent substrate; (c) an EL layer element disposed over the first electrode providing a light-emissive function for producing light, (d) a second electrode layer disposed over the EL layer, at least one of the first and second electrodes may be transparent, wherein such light-emitting device may be a top-emitting, bottom emitting or dual emitting LED, and (e) a light enhancing layer including a layer having surface corrugations with controlled length scale, wherein the surface corrugations are formed from a self-assembled layer of nanoparticles having fluorinated organic functional groups bonded thereto.

In one aspect applicable to various embodiments of the invention, the light emitting device, further includes a thin metal layer disposed over the layer having surface corrugation. This construction offers a transparent electrode with additionally enhanced light output.

In one embodiment of the invention the thin metal layer has a thickness of from about 10 to about 70 nm.

In another embodiment of the invention, thin metal layer is based on silver, gold or aluminum or a mixture or alloy thereof with another metal.

According to still another embodiment of the present invention, there is provided a structure capable of enhancing light output of a light emitting device, such structure including a layer having surface corrugations with controlled wavelength scale, wherein the surface corrugation is formed from a self-assembled layer of nanoparticles having fluorinated organic functional groups bonded thereto and a thin metal layer disposed over the surface corrugations.

### DETAILED DESCRIPTION AND EXEMPLARY EMBODIMENTS

In embodiments of the present invention, a binder in the coating composition, is a functionalized silica sol containing both silanol groups and polymerizable moieties such as acrylic, vinyl or epoxy groups. In addition to condensation of silanol to form siloxane bonds (Si—O—Si), the polymerizable groups chemically connected to the Si atom can be further cured with UV-radiation or thermally and form a highly crosslinked polymeric network.

In addition to the coating emitting surface of the light emitting devices, it is known from the literature that Bragg scattering from a periodic photonic structure can extract light from the surface plasmon polariton mode and other waveguide modes trapped in the substrate of an OLED. Here a microstructure in the form of a diffraction grating (pitch λ_{g}) allows the wavevector of the SPPs to be augmented/reduced by Bragg scattering from the periodic structure according to Equation 1,

k_{SPP}±nk_{g}=k₀ sin θ Equation 1

where k_{SPP} is the wavevector of the SPP mode, k_{g} is the grating wavevector (|k_{g}|=2π/λ_{g}), k₀ sin θ is the in-plane wavevector, θ the angle of the emitting light and n is an integer that defines the order of the scattering process. Therefore SPP modes may be scattered and outcouple to the emitting light. Likewise, the nanocorrugated surface according to embodiments of the invention, at an optimized wavelength scale created by this functional coating, can also be used to couple the surface plasmon modes out to the emitting light. In embodiments of the present invention, with a low refractive index and anti-reflective in nature, the functional coating can be applied inside the multi-layer microcavity structures of an OLED to recover light out of the device. Different from the hydrophobic aerogel layer reported by Tsutsui (2001), the nanocorrugated coating structure according to embodiments of the present invention can be easily integrated with thin film metal technology to further substantially enhance light extraction by surface plasmon coupled emission, in both bottom- and top-emitting OLEDs.

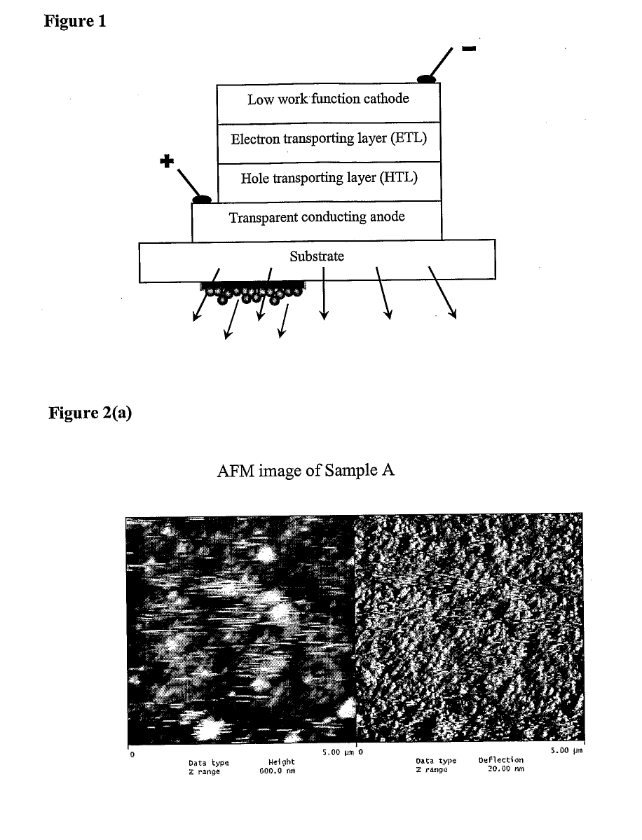

In this regard, as schematically illustrated in FIG. 1, a representative bottom emitting OLED device includes a transparent substrate and a transparent conducting anode layer deposited on an inner surface of the substrate. An EL layer overlies the transparent anode and, in the embodiment illustrated, the EL layer includes a hole transporting layer (HTL) overlying the anode and an electron transporting layer (ETL) overlying the HTL layer. A cathode layer, typically of a reflecting metal material, or a separate layer of reflecting material, such as silver, aluminum or alloys thereof with each other and/or with other metals, overlies the ETL layer. In the case of a top-emitting layer (not illustrated), the cathode layer is formed from a transparent material and the anode is formed from a suitable reflecting material, such as metal, alloy or semiconductor, for example, silver, aluminum or alloys thereof, e.g., lithium-aluminum, calcium-silver, and the like.

As previously disclosed in the commonly assigned pending U.S. application Ser. No. 10/514,018, filed Nov. 10, 2004, which claims priority from International Publication No. WO04/027517, published Apr. 1, 2004, and in the concurrently filed International application claiming priority to U.S. Provisional Application No. 60/656,096, filed Feb. 25, 2005 and entitled “Inorganic-organic hybrid nanocomposite antiglare and antireflection coatings,” and the entire disclosures of which are incorporated herein by reference, fluorocarbon surface modified silica particles (F-silica) may be made by a modified Stöber process. The starting silica source may be a mixture of alkoxysilane and fluoroalkoxysilane. Typically, tetraethoxysilane (TEOS) and for example, (tridecafluoro-1,1,2,2-tetrahydrooctyl)triethoxysilane (F-TEOS) are used to prepare these fluoro-containing silica particles. The reaction medium is a low viscosity solvent, such as, isopropanol, and the catalyst may be a basic catalyst, such as, ammonia. The particle sizes of the particles from this process are measured by light scattering (90 Plus Particle Size Analyzer, Brookhaven Instruments Corporation). The medium for particle sizing was ethanol. Generally, particles with average particle size in the range of 20 nm to 600 nm, in particular, 100 nm to 400 nm, have been prepared. The fluorocarbon content in the particles is calculated based on the molar ratios of the reactants. The fluorocarbon contents of the particles used in the coating compositions may be in the range of 5 to 20% based on the molar ratio. The fluorine atoms can significantly reduce the surface free energy and the refractive index of the particles. The particles can be dispersed homogenously for example, in isopropanol or other low molecular weight alcohol or other low viscosity solvent. In order to facilitate the migration of F-silica particles during the application of the coating onto a substrate, a coating solution with low viscosity is preferred.

The ability to incorporate additional organic functional groups to F-silica particles is a significant advantage of embodiments of this invention. In a typical procedure, a functional silane coupling agent is added into the F-silica suspension after the freshly prepared particles have been aged for at least 2 hours. The silane coupling agent hydrolyzes and partially condenses at the surface of the F-silica particles. The resulting F-silica particle suspension contains organic functional groups, which can promote not only better adhesion between particles and the binders, but may also improve refractive index matching in the coating formulation.

Further, according to embodiments of the invention, the F-silica particle exposed on the top surface for the creation of surface corrugation can be modified by, for example, hexamethyldisilazane. According to this embodiment, the concentration of the silanol groups of the coating surface is reduced, thereby, imparting hydrophobic properties to the coating and improving anti-staining capability.

The functionalized silica sol may be prepared by using tetra-alkoxysilane and alkyl-alkoxysilane mixture as starting compounds. The general formula of the tetraalkoxysilane is SiX₄, in which each moiety X is the same or different hydrolysable group. The general formula of the functional group containing silane may be R¹ₙR²ₘSiX₍₄₋ₙ₋ₘ₎, in which R¹ and R² are non-hydrolyzable moieties with or without carrying functional groups; each X is the same or different hydrolysable group, n and m are each independently, 0, 1, 2 or 3 and the sum n+m≦3. The hydrolysable radicals X can be, for example, halogen, alkoxy and or alkylcarbonyl. An alkoxy with low molecular weight, such as methoxy, ethoxy, n-propoxy, iso-propoxy, and butoxy are preferably used. The functional groups on the radicals R₁ or R₂ may be polymerizable moieties such as vinyl, acryloxy, methacryloxy and/or epoxy. These are readily available in a variety of commercially available or easily formed silane coupling agents.

The molar ratios of tetraalkoxysilane to functional alkyltrialkoxysilane in stock mixture are generally in the range 98:2 to 50:50. The basic chemistry of formation of the organic moiety contained silica sol is by hydrolysis and condensation of silanes in acidic media. In a predetermined reaction condition, the hydrolysis and partial condensation of the silanes leads to the formation of an organic modified silica oligomer. Both the silanol group and organic functional group on the silica oligomer are active at a certain condition which can then be polymerized into a highly crosslinked hybrid network at that condition.

The coated functional coating (e.g, functionalized silica sol) according to embodiments of the invention, may be used as a binding matrix for particles, such as, for example, metal (e.g., silver, gold, aluminum) nanoparticles, metal (e.g., silver, gold, aluminum)-silica core-shell nanoparticles, high efficiency phosphor materials (e.g., quantum dots, fluorescent core-shell nanoparticles).

In addition to using the functionalized silica sol as a binder, polymerizable monomers and/or oligomers with di- or multi-functional groups can be used as binders as well. As a result, there will be a wide range of monomers or oligomers that can be chosen for better matching the properties between the substrate and coating. These organic monomers or oligomers, containing one or several polymerizable groups, can be thermally or photochemically induced to polymerize into crosslinked inorganic-organic hybrid networks. In the coating composition of embodiments of the invention, the effective binder plays a critical role to bridge F-silica particles and the substrate. The coating matrix is a hybrid composite based on organic silica sol and organic monomer or oligomer.

The coating mixture according to embodiments of the present invention also may contain a catalyst for thermally or/and photochemically induced curing of the coating matrix. Thermal initiators used include, for example, organic peroxides such as dialkyl peroxides, diacyl peroxides and alkyl hydroperoxides. Photoinitiators, such as, 1-hydroxycyclohexyl phenyl ketone, benzophenone, 2-isopropyl thioxanthone may be used for the coating composition which can be cured with UV-radiation. Cationic photoinitiators, such as, iodonium and sulfonium salts of hexafluoroantimonic acids may be used to initiate the UV curing of functional sol containing epoxy moiety. The initiator amount added is based on the coating compositions and generally, amounts in the range of about 1 wt % to about 5 wt % based on solid content of the coating mixture are expected to be useful. The coating may also be cured with electron-beam radiation without the use of initiators.

The coating mixture may be applied onto an appropriate substrate using, for example, a dip coating method or a spin coating method, as well known in the art. The applied coating is preferably dried before curing. The drying temperature may preferably be in the range of about 50° C. to about 150° C. depending on the processing requirements of the substrate used. Preferred coating thickness after curing ranges from about 0.1 to about 5 microns. The preferred substrates are plastics or inorganic glasses.

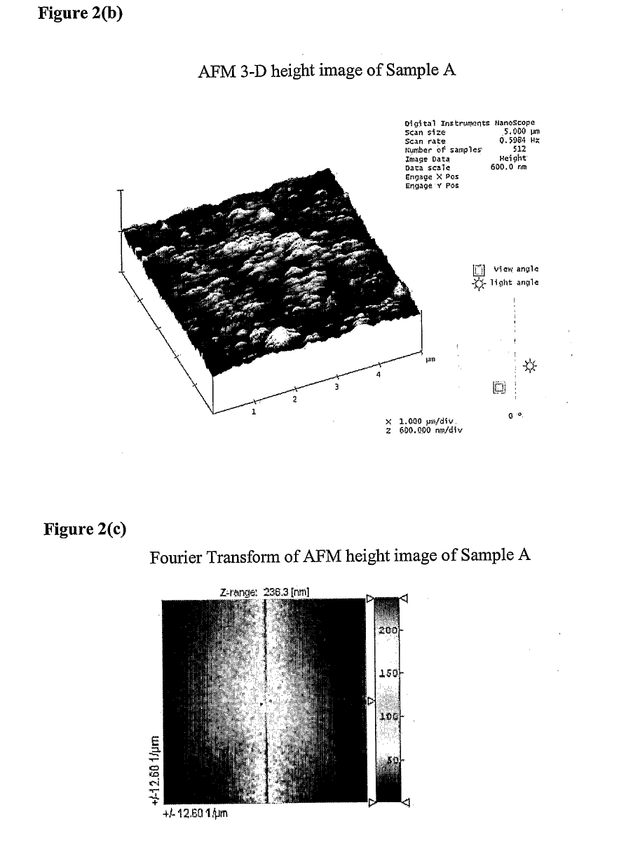

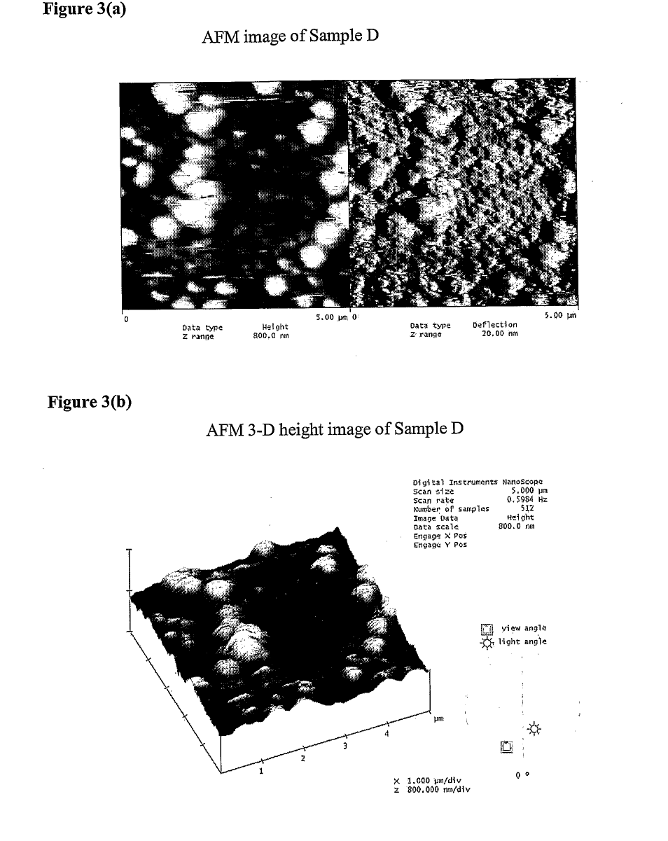

The roughened surface topography is herein characterized by atomic force microscopy (AFM) using a Digital Instrument Dimension 3000 AFM. The images are collected by contact mode. A typical 5×5 micron size height and phase image is shown in FIGS. 2(a) and 3(a) for Example A and Example D, respectively. For a better visual effect, the 3-D contour profile of the height images have been demonstrated by FIGS. 2(b) and 3(b), respectively. In order to find out the characteristic correlation distance in the roughened surface, the Fourier transform of the AFM height images are performed accordingly in FIGS. 2(c) and 3(c), respectively. A characteristic correlation distance can be obtained at the peak positions for Example A (236 nm), Example B (701 nm), Example C (424 nm) and Example D (486 nm).

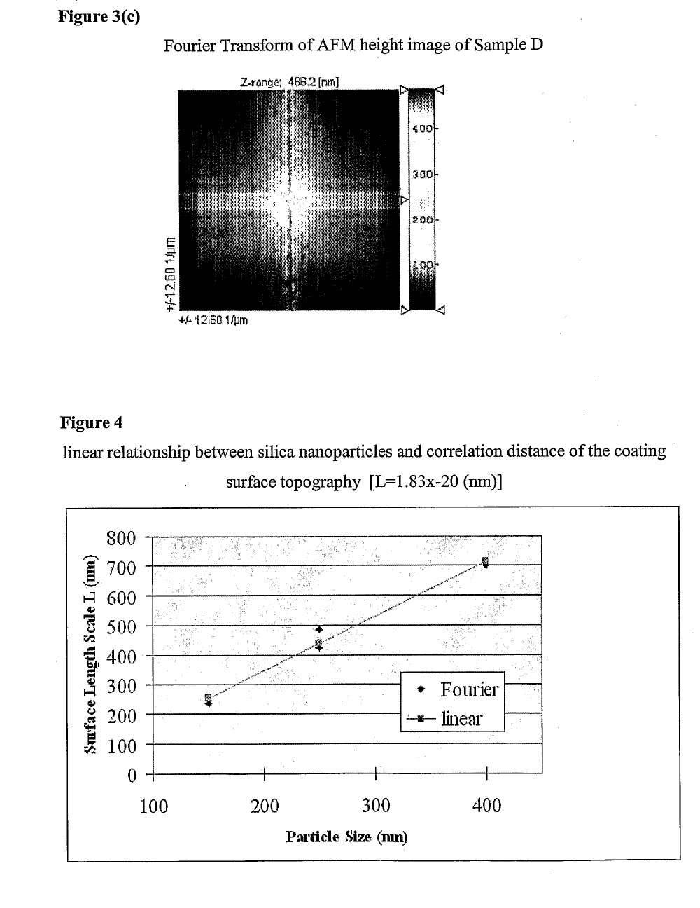

The silica nanoparticles prepared for the coating formulation may easily cover a size range of which may be between 100 nm to 600 nm, especially between 120 nm to 600 nm. The surface roughness and the correlation distance of the surface microstructures are determined by AFM. It has been found that the correlation surface length scale has a linear relationship with the size of the silica particles used in the coating (see, FIG. 4). This invention is able to create well-controlled functional coating surface microstructure simply by adjusting the size of the silica nanoparticles in the formulation and coating conditions. The surface corrugation length scale (L in FIG. 4), adjustable from 200 to 1000 nm by the coating methods disclosed in various embodiments of the invention, covered the whole range of the visible spectra, thereby providing simple schemes for enhancing light output of LED and OLED.

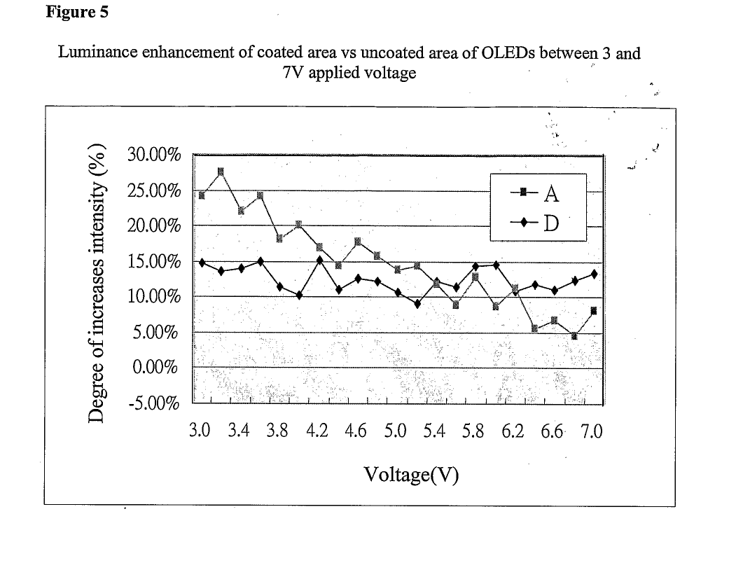

The optical functional coatings of Examples A to G have been applied onto the emitting glass surface of OLEDs. Using a dip coating method to apply the coating to half of the emitting surface, the light emission between the coated and uncoated area in the range of applied voltage between 3V and 7V, were compared. The results demonstrate that the embodiments of the present invention are able to control the details of surface corrugation by adjusting the particle size in the coating and showed up to 28% and 15% improvement between 3V and 7 V for Examples A and D, respectively, in light emission, as illustrated in FIG. 5. In addition, the testing results from RitDisplay Corporation further confirmed that the enhancement of light output does not cause shift in the CIE coordination. This is apparent from the results reported in Table 1. The luminance enhancements at 7V for Examples A, B, C, and D are 8%, 25%, 19%, 8%, respectively.

According to literature results by Lupton et al, as well as Lakowicz and his coworkers, a thin (e.g., 15 nm to about 50 nm) silver layer deposited on top of a corrugated surface will demonstrate a directional and enhanced light emissions when the surface corrugation length scale is controlled in the visible wavelength range. Thus, for those skilled in the art of making such devices, it becomes possible to integrate the various embodiments of the present invention with the deposition of silver (or other suitable metal) thin layer for further enhancements in both top-emitting and bottom-emitting OLEDs. Furthermore, the current trend of making top-emission OLEDs requires a transparent metal cathode. In embodiments of the present invention, by appropriate adjustment in metal layer thickness, it becomes possible to produce high-output, top-emitting OLEDs without major changes in their design and processing.

TABLE 1
Luminance enhancement of coated area vs uncoated area of OLEDs
at 7 V applied voltage (courtesy to RitDisplay Corporation for the testing
results)

| Name | V | Lum | CIE-x | CIE-y |
|---|---|---|---|---|
| typeA-L-no coating | 7.00 | 5400.00 | 0.166 | 0.2697 |
| typeA-R-coating | 7.00 | 5854.00 | 0.166 | 0.2700 |
| typeB-L-no coating | 7.00 | 5232.00 | 0.162 | 0.2592 |
| typeB-R-coating | 7.00 | 6540.00 | 0.163 | 0.2583 |
| type C-L-no coating | 7.00 | 4879.00 | 0.165 | 0.2680 |
| type C-R-coating | 7.00 | 5787.00 | 0.164 | 0.2670 |
| type D-L-no coating | 7.00 | 4447.00 | 0.164 | 0.2700 |
| type D-R-coating | 7.00 | 4801.00 | 0.165 | 0.2688 |

### EXAMPLES

### Example 1 to Example 4

### Fluorinated Silica Particle Preparation

### Example 1

In a reaction vial, 100 ml isopropanol (IPA), 14 ml tetraethoxysilane (TEOS) and 6 ml tridecafluoro-1,1,2,2-tetrahydrooctyl)triethoxysilane (F-TEOS) were added and mixed with a magnetic stirrer at a high speed for two minutes. While stirring, between 0.5 and 20 ml deionized water and between 0.5 and 10 ml concentrated ammonia solution (NH₃ 28-30 wt % in water) were added into the mixture. The mixture was stirred over a period of 30 to 240 minutes. The initially clear mixture became a translucent suspension. The suspension was aged for two days and then the particle size was determined by laser light scattering. The medium for particle sizing was ethanol. The particle suspensions were treated by ultrasound for 5 to 10 minutes before particle sizing. The fluoro-content in the particles was calculated based on the molar ratios of the reactants.

The average particle diameter prepared from above procedure is about 120 nm. The molar ratio of F-containing silica to pure silica in the particles is 20:80.

### Example 2

In a reaction vial, 100 ml isopropanol, 14 ml (TEOS) and 2.6 ml (F-TEOS) were added and mixed with a magnetic stirrer at a high speed for two minutes. During the stirring, between 0.5 and 20 ml of deionized water and between 0.5 and 20 ml concentrated ammonium hydroxide solution (NH₃ 28-30 wt %) were added to the mixture. The mixture was stirred over a period of 30 to 240 minutes. The initially clear mixture develops into an opaque white suspension. The suspension was subsequently aged for two days and then the particle size was determined by laser light scattering. The particle size is around 400 nm. The molar ratio of F-containing silica to pure silica in the particles is 10:90.

### Example 3

In a reaction vial, 100 ml isopropanol, 14 ml TEOS and 6 ml F-TEOS were added and mixed with a magnetic stirrer at a high speed for two minutes. During the stirring, between 0.5 and 20 ml of deionized water and between 0.5 and 20 ml concentrated ammonium hydroxide solution (NH₃ 28-30 wt %) were added to the mixture. The mixture was stirred over a period of 30 to 240 minutes. The initially clear mixture develops into an opaque white suspension. The suspension was subsequently aged for two days and then the particle size was determined by laser light scattering. The particle size is around 250 nm. The molar ratio of F-containing silica to pure silica in the particles is 20:80.

### Example 4

In a reaction vial, 100 ml isopropanol, 14 ml TEOS and 6 ml F-TEOS were added and mixed with a magnetic stirrer at a high speed for two minutes. During the stirring, between 0.5 and 20 ml of deionized water and between 0.5 and 20 ml concentrated ammonium hydroxide solution (NH₃ 28-30 wt %) were added to the mixture. The mixture was stirred over a period of 30 to 240 minutes. The initially clear mixture develops into an opaque white suspension. The suspension was subsequently aged for two days and then the particle size was determined by laser light scattering. The particle size is around 92 nm. The molar ratio of F-containing silica to pure silica in the particles is 20:80.

### Example 5 to Example 8

### Functionalized Silica Sol Preparation

### Example 5

In a reaction vial, 50 ml IPA and a volume between 0.5 ml and 30 ml TEOS were added and mixed with a magnetic stirrer for a couple of minutes. During the stirring, a volume between 0.5 ml and 20 ml deionized water was added and sequentially a volume between 0.5 ml and 20 ml 0.2 M HCl/H₂O was added into the mixture. The pH of the mixture was around 1.5. The mixture was stirred for two hours at room temperature. A clear solution is obtained. This solution was subsequently aged for a minimum of one day before being used in the coating formulation.

### Example 6

In a reaction vial, 60 ml IPA and 18 ml TEOS were added and mixed with a magnetic stirrer for a couple of minutes. During the stirring, a volume between 0.5 ml and 20 ml deionized water was added and sequentially a volume between 0.5 ml and 20 ml 0.2 M HCl/H₂O was added into the mixture. The mixture was stirred for two hours at room temperature. A clear solution is obtained. This solution was subsequently aged for a minimum of one day before being used in the coating formulation.

### Example 7

In a reaction vial, 50 ml IPA, 30 ml TEOS and 1.67 g methacryloxy propyl methyldimethoxysilane were added and mixed with a magnetic stirrer for a couple of minutes. During the stirring, a volume between 0.5 ml and 20 ml 0.2 M HCl/H₂O was added into the mixture. The mixture was stirred for two hours at room temperature. A clear solution is obtained. This solution was subsequently aged for a minimum of one day before being used in the coating formulation. The acrylate content in the silica sol was calculated based on the molar ratios of the reactants. In this case, the molar ratio composition of the acrylate is 5%.

### Example 8

In a reaction vial, 50 ml IPA, 7.5 ml TEOS, 3.18 ml F-TEOS and 0.24 g (3-Glycidoxypropyl) trimethoxysilane (G-TMOS) were added and mixed with a magnetic stirrer for a couple of minutes. During the stirring, a volume between 0.5 ml and 20 ml 0.2 M HCl/H₂O was added into the mixture. The mixture was stirred for two hours at room temperature. A clear solution is obtained. This solution was subsequently aged for a minimum of one day before being used in the coating formulation. The molar ratio composition of the epoxy is 3%. The molar ratio of F content in the sol is 20%.

### Example 9 to Example 11

### Particle Functionalization

### Example 9

In a reaction vial, 100 ml isopropanol, 14 ml (TEOS) and 6 ml (F-TEOS) were added and mixed with a magnetic stirrer at a high speed for two minutes. During the stirring, a volume between 0.5 ml and 20 ml Di-water and a volume between 0.5 ml and 20 ml concentrated NH₃/H₂O solution (NH₃ 28-30 wt %) were added into the mixture. The mixture was stirred over a time range of 30 to 240 minutes. The clear mixture develops into a white suspension. The suspension was aged for 2.5 hours and then 0.9 g MA-TMOS was added with stirring for 10 minutes. The suspension was then aged for two days before being used in the coating formulation. The acrylate content in the silica particle suspension was calculated based on the molar ratios of the TEOS and MA-TMOS. In this case, the molar ratio composition of the acrylate is 5%. The particle size is around 160 nm. The molar ratio of F-containing silica to pure silica in the particles is 20:80.

### Example 10

To the suspension of the silica particles obtained from Example 9, 1.12 g hexamethyldisilazane was added and mixed with a magnetic stirrer at a high speed for from 15 minutes to 120 minutes. The translucent suspension was then aged for at least one day before being used in the coating formulation. The methylation to the silanol groups was calculated based on the molar ratios of the TEOS and hexamethyldisilazane. In this case, the molar ratio of methylation is 10%.

### Example 11

In a reaction vial, 100 ml isopropanol, 14 ml (TEOS) and 6 ml (F-TEOS) were added and mixed with a magnetic stirrer at a high speed for two minutes. During the stirring, a volume between 0.5 ml and 20 ml DI-water and a volume between 0.5 ml and 20 ml concentrated NH₃/H₂O solution (NH₃ 28-30 wt %) were added into the mixture. While continuing to stir for about a time range of 30 to 240 minutes, the clear mixture develops into white suspension. The suspension was aged for 2.5 hours and then 0.62 g (3 Glycidoxypropyl) trimethoxysilane (G-TMOS) was added to the suspension. The suspension was stirred for 10 minutes and then aged for two days before being used in the coating formulation. The epoxy content in the silica particle suspension was calculated based on the molar ratios of the TEOS and G-TMOS. In this case, the molar ratio composition of the epoxy is 4%. The particle size is around 160 nm. The molar ratio of F-containing silica to pure silica in the particles is 20:80.

### Example A to Example G

### Functional Coating Formulation

This is a typical method used for formulating and application of the coating: In a suitable container, a certain amount of F-silica particle/IPA suspension and IPA solvent were added and mixed. Then functionalized silica sol, organic monomer or/and oligomer, and photo-initiator dissolved in the IPA were added. The mixture was stirred and then sonicated in an ultrasonic bath for 5 minutes. After sonication, the mixture was ready to be used for dip coating. A clear and flat substrate was then dipped into the solution at different speeds to achieve different film thickness and surface topography. The coating was first dried at a temperature in the range between 40° C. and 100° C. The dried coating was then transferred to a UV-curing machine to be cured with a conveyor speed 25 fpm and radiation 300 WPI (watts per inch).

### Example A

To 5.0 g F-silica particle/IPA suspension from Example 1, 45 g IPA was added and stirred to make the dispersion homogeneous. To the suspension, 2.5 g silica sol (from Example 5) containing 3% photo-initiator was added. After sonication of the coating solution, a clear and flat substrate is dipped into the solution once at a constant speed of 7 cm/min. The coating was dried at the temperature of 70° C. and then cured with the UV-curing machine.

### Example B

To 5.0 g F-silica particle IPA suspension from Example 2, 45 g IPA was added and stirred to make the dispersion homogeneous. To the suspension, 2.5 g silica sol (from Example 5) containing a 3% photo-initiator was added. After sonication of the coating solution, a clear and flat substrate is dipped into the solution twice at a constant speed of 2.5 cm/min. The coating was dried at a temperature of 70° C. and then cured with the UV-curing machine.

### Example C

To 5.0 g F-silica particle IPA suspension from Example 3, 45 g IPA was added and stirred to make the dispersion homogeneous. To the suspension, 2.5 g silica sol (from Example 6) containing 3% photo-initiator was added. After sonication of the coating solution, a clear and flat substrate is dipped into the solution twice at a constant speed of 5 cm/min. The coating was dried at a temperature of 70° C. and then cured with the UV-curing machine.

### Example D

To 5.0 g F-silica particle IPA suspension from Example 3, 45 g IPA was added and stirred to make the dispersion homogeneous. To the suspension, 2.5 g silica sol (from Example 6) containing a 3% photo-initiator was added. After sonication of the coating solution, a clear and flat substrate is dipped into the solution once at a constant speed of 17 cm/min. The coating was dried at a temperature of 70° C. and then cured with the UV-curing machine.

### Example E

To 5.0 g F-silica particle IPA suspension from Example 9, 45 g IPA was added and stirred to make the dispersion homogeneous. To the suspension, 2.5 g silica sol (from Example 6) containing a 3% photo-initiator was added. After sonication of the coating solution, a clear and flat substrate is dipped into the solution once at a constant speed of 7 cm/min. The coating was dried at a temperature of 70° C. and then cured with the UV-curing machine.

### Example F

To 5.0 g F-silica particle IPA suspension from Example 11, 45 g IPA was added and stirred to make the dispersion homogeneous. To the suspension, 2.5 g silica sol (from Example 8), 0.3 g Etercure 6145-100 (from Eternal Chemical Co., Ltd.) and 3% photo-initiator were added. After sonication of the coating solution, a clear and flat substrate is dipped into the solution once at a speed of 7 cm/min. The wet coating was dried at a temperature of 70° C. and then cured with the UV-curing machine.

### Example G

In 5.0 g F-silica particle IPA suspension from Example 10, 45 g IPA was added and stirred to make the dispersion homogeneous. Then 2.5 g silica sol (from Example 7) and 3% photo-initiator were added. After sonication of the coating solution, a clear and flat substrate is dipped into the solution once at a speed of 7 cm/min. The wet coating was dried at a temperature of 70° C. and then cured with the UV-curing machine.

### CITED LITERATURE

M. Ibn-Elhaj et al., “Optical polymer thin films with isotropic and anisotropic nano-corrugated surface topologies” Nature, Vol. 410, pp. 796-799 (2001)
A. Zukauskas, M. S. Shur, R. Gaska, Introduction to Solid State Lighting, John Wiley & Sons, Inc., New York, (2002)
J. Shinar, Editor, Organic light-emitting devices: a survey, Springer-Verlag New York, Inc., (2004)
H. Raether, Surface plasmons on smooth and rough surfaces and on gratings, Springer-Verlag, Berlin, (1988)
S. Wedge et al., “Surface plasmon-polariton mediated light emission through thin metal films” Optics Express, Vol. 12, No. 16, pp. 3673-3685 (2004)
L. H. Smith et al., “Light outcoupling efficiency of top-emitting organic light-emitting diodes”, Applied Physics Letters, Vol. 84, No. 16, pp. 2986-2988 (2004)
J. R. Lawrence et al., “Optical properties of a light-emitting polymer directly patterned by soft lithography” Applied Physics Letters, Vol. 81, No. 11, pp. 1955-1957 (2002)
D. K. Gifford et al., “Extraordinary transmission of organic photoluminescence through an otherwise opaque metal layer via surface plasmon cross coupling” Applied Physics Letters, Vol. 80, No. 20, pp. 3679-3681 (2002)
J. M. Lupton et al., “Bragg scattering from periodically microstructured light emitting diodes” Applied Physics Letters, Vol. 77, No. 21, pp. 3340-3342 (2000)
I. Schnitzer and E. Yablonovitch et al., “30% external quantum efficiency from surface textured, thin-film light-emitting diodes” Applied Physics Letters, Vol. 63, No. 16, pp. 2174-2176 (1993)
T. Yamasaki et al., “Fabrication and Optical Properties of Two-Dimensional Ordered Arrays of Silica Microspheres” Japanese Journal of Applied Physics, Vol. 38, pp. 5916-5921 (1999)
T. Tsutsui et al., “Doubling coupling-out efficiency in organic light-emitting devices using a thin silica aerogel layer” Advanced Materials, Vol. 13 pp. 1149-1152 (2001)
J. R. Lakowicz, “Radiative decay engineering 3. Surface plasmon-coupled directional emission” Analytical Biochemistry, Vol. 324, No. 1, pp. 153-169 (2004)
J. R. Lakowicz, “Radiative decay engineering 5, metal-enhanced fluorescence and plasmon emission” Analytical Biochemistry, Vol. 337, No. 1, pp. 171-194 (2005)

1. A method for controlling surface corrugation on an emitting surface of a light-emitting device (LED) comprising applying to said surface a functional coating comprising nanoparticles having fluorinated organic functional groups bonded thereto.

2. The method of claim 1 wherein the light emitting device is an organic light emitting device (OLED).

3. The method of claim 1, wherein said functional coating comprises at least substantially spherical silica nanoparticles with fluorine functional groups, wherein the particle size ranges from about 20 nm to about 600 nm.

4. The method of claim 1, wherein said functional coating comprises silica sol with organic functional groups.

5. The method of claim 1, wherein said functional coating comprises a photo-initiator.

6. The method of claim 1, wherein said functional coating comprises a mixture of fluorinated silica particles, silica sol, and a photo-initiator.

7. The method of claim 1, wherein said functional coating comprises polymerizable monomers and/or oligomers with di- or multi-functional groups.

8. The method of claim 1, wherein said functional coating comprises a mixture of fluorinated silica particles, said polymerizable monomers and/or oligomers with di- or multi-functional groups, and a photo-initiator.

9. The method of claim 6, wherein said functional coating is formed by dip coating or spin coating said surface with a precursor solution to form a mixture of the silica nanoparticles and polymeric binder.

10. The method of claim 9, wherein said dip coated or spin coated functional coating is heat treated at a temperature ranging from about 40° C. to about 100° C. for a period ranging from about 1 minute to about 300 minutes.

11. The method of claim 10, wherein said dip coated or spin coated functional coating is subsequently treated under UV radiation.

12. The method of claim 1, further comprising applying a thin metal coating on top of the corrugated surface.

13. The method of claim 12, wherein the thin metal coating is applied by sputtering.

14. The method of claim 13, wherein the thin metal coating comprises silver, gold or aluminum.

15. The method of claim 12, wherein the thin metal coating has a thickness of from about 30 to about 50 nm.

16. The method of claim 9, wherein said dip or spin coated functional coating comprises a binding matrix for particles selected from the group consisting of metal nanoparticles, metal-silica core-shell nanoparticles and high efficiency phosphor materials.

17. The method of claim 16, wherein said particles comprise said high efficiency phosphor materials in the form of quantum dots or fluorescent core-shell nanoparticles.

18. A method for enhancing light extracting efficiency of a light emitting device, comprising applying to the emitting surface of an LED or an OLED device a coating comprising a precisely controlled corrugated surface, said coating comprising a functional coating comprising sol-gel nanoparticles having fluorinated organic functional groups bonded thereto.

19. A method for enhancing light extraction efficiency of a light emitting device, comprising applying inside the multilayer microcavity structure of an OLED device a coating comprising a precisely controlled corrugated surface, said coating comprising a functional coating comprising sol-gel nanoparticles having fluorinated organic functional groups bonded thereto and a conformal metal layer of thickness range of 5 to 50 nm.

20. A method for achieving a lotus-leaf effect on a substrate, comprising applying to said substrate a precisely controlled functional coating comprising nanoparticles having fluorinated organic functional groups bonded thereto.

21. A light-emitting element comprising:
a light-emitting layer; and
at least one light-extracting portion;
wherein a part of the at least one-light extracting portion comprises surface corrugation with controlled length scale correlating with the desired light enhancement wavelength, wherein said surface corrugation comprises a self-assembled layer of nanoparticles with controlled size and having fluorinated organic functional groups bonded thereto to facilitate assembling at the surface layer.

22. A method for improving the light-emitting efficiency of a light-emitting device which includes (a) a substrate, (b) a first electrode disposed over the substrate, (c) an organic EL element disposed over the first electrode providing a light-emissive function for producing light, (d) a second electrode layer disposed over the EL layer, wherein at least one of the first and second electrodes may be transparent, wherein such light-emitting device could be a top-emitting, bottom-emitting or dual emitting LED depending on the choice of light output (transparent) sides; said method comprising applying to at least one of layers (a)-(d) a surface corrugated layer with a controlled length scale optimized for light extraction and comprising a self-assembled layer of nanoparticles having fluorinated organic functional groups bonded thereto and thereby providing the desired surface corrugation at the optimized length scale.

23. A method according to claim 22, wherein the light extraction layer is created with the further integration of the controlled surface corrugation with a deposition of a conductive metal nanolayer for constructing a transparent electrode with additionally enhanced light output.

24. An enhanced light-emitting device comprising:
(a) a transparent substrate;
(b) a first electrode layer disposed over a first surface of the transparent substrate;
(c) an EL layer element disposed over the first electrode providing a light-emissive function for producing light,
(d) a second electrode layer disposed over the EL layer, and
(e) a light enhancing layer comprising a layer having surface corrugation with a controlled and optimized length scale correlating with the wavelength of desired light enhancement, wherein said surface corrugation comprises a self-assembled layer of nanoparticles having fluorinated organic functional groups bonded thereto to thereby facilitate assembling at the surface layer and to accomplish the desired surface corrugation at the optimized length scale.

25. The light emitting device of claim 24, further comprising a thin metal layer disposed over the layer having surface corrugation.

26. The light emitting device of claim 25, wherein the thin metal layer has a thickness of from about 10 to about 70 nm.

27. The light emitting device of claim 25, wherein the thin metal layer comprises silver, gold or aluminum or a mixture or alloy thereof with another metal.

28. A structure capable of enhancing light output of a light emitting device, comprising a layer comprising surface corrugations with controlled length scale, wherein said surface corrugation comprises a self-assembled layer of nanoparticles having fluorinated organic functional groups bonded thereto and a thin metal layer disposed over the surface corrugations.

29. The method of claim 8, wherein said functional coating is formed by dip coating or spin coating said surface with a precursor solution to form a mixture of the silica nanoparticles and polymeric binder
